(19) United States
(12) Patent Application Publication
(10) Pub. No.: US 2025/0239492 A1
(43) Pub. Date: Jul. 24, 2025

(54) DEFORMATION CONTROL FOR DIE-TO-WAFER AND DIE-TO-DIE BONDING IN DEVICE MANUFACTURING

(71) Applicant: Applied Materials, Inc., Santa Clara, CA (US)

(72) Inventors: San-Kuei Lin, Los Gatos, CA (US); Wonjae Lee, Fremont, CA (US); Pradeep Kumar Subrahmanyan, San Jose, CA (US)

(21) Appl. No.: 19/019,449

(22) Filed: Jan. 13, 2025

Related U.S. Application Data
(60) Provisional application No. 63/623,125, filed on Jan. 19, 2024.

(51) Int. Cl. H01L 21/78; H01L 21/66

(52) U.S. Cl. CPC H01L 21/78; H01L 22/12

(57) ABSTRACT

Disclosed systems and techniques are directed to optimization of semiconductor manufacturing by forming features on a front side of a first substrate and covering the plurality of first features with a stress-compensation layer (SCL). The techniques further include causing the first substrate to adhere to a second substrate and removing a back side portion of the first substrate to expose at least a subplurality of the features and forming a plurality of devices, each device including a portion of the features, a portion of the first substrate, and a portion of the second substrate. The SCL is configured to reduce deformation of the plurality of devices.

### RELATED APPLICATIONS

This application claims the benefit of the U.S. Provisional Patent Application No. 63/623,125, entitled “DEFORMATION CONTROL FOR DIE-TO-WAFER AND DIE-TO-DIE BONDING IN DEVICE MANUFACTURING,” filed Jan. 19, 2024, the entire contents of which are being incorporated in their entirety by reference herein.

### TECHNICAL FIELD

The disclosure pertains to semiconductor manufacturing, including processing of wafers and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### BRIEF DESCRIPTION OF THE DRAWINGS

The present disclosure will be understood more fully from the detailed description given below and from the accompanying drawings of various embodiments of the disclosure.

FIG. 1 illustrates schematically stresses in an example wafer structure that can be mitigated using the techniques of the instant disclosure.

FIGS. 2A-2X illustrate a process of die-to-die and/or die-to-wafer semiconductor manufacturing that deploys stress-compensation layers, according to at least one embodiment.

FIGS. 3A-3E illustrate schematically a process of correcting a wafer deformation using a stress-modulation beam applied to the back side of a wafer, according to at least one embodiment.

FIG. 4 illustrates an example Zernike polynomial decomposition of one actual deformation (top left) of a wafer, in arbitrary units, into a paraboloid bow deformation (top right), a saddle deformation (bottom left), and a residual deformation, (bottom right), according to at least one embodiment.

FIG. 5A-5B are flowcharts illustrating an example method of mitigation of wafer stress and deformation using stress-compensation beams, in accordance with at least one embodiment.

FIG. 6 is a flowchart illustrating an example method of determining settings for beam irradiation, in accordance with at least one embodiment.

FIGS. 7A-7B illustrates schematically an irradiation system capable of performing irradiation of stress compensation layers, according to at least one embodiment.

FIG. 8 depicts a block diagram of an example computer system capable of supporting operations of the present disclosure, according to at least one embodiment.

### SUMMARY

Disclosed herein, according to one embodiment, is a method of manufacturing of manufacturing one or more devices, the method including forming a plurality of first features on a first side of a first substrate, covering the plurality of first features with a stress-compensation layer (SCL), causing a second substrate to adhere to the first substrate on a first side covered with the plurality of first features and the SCL, thinning the first substrate to expose at least a subset of features of the plurality of first features, and forming the one or more devices. Each device of the one or more devices includes a portion of the plurality of first features, a portion of the first substrate, and a portion of the second substrate. The SCL is selected to reduce deformation of the one or more devices.

In another embodiment, disclosed is a system for manufacturing one or more devices, the system includes a memory device and a processing device communicatively coupled to the memory. The processing device causes performance of operations that includes forming a plurality of first features on a first side of a first substrate, covering the plurality of first features with an SCL, causing a second substrate to adhere to the first substrate on a first side covered with the plurality of first features and the SCL, thinning the first substrate to expose at least a subset of features of the plurality of first features, and forming the one or more devices. Each device of the one or more devices includes a portion of the plurality of first features, a portion of the first substrate, and a portion of the second substrate. The SCL is selected to reduce deformation of the one or more devices.

In yet another embodiment, disclosed is a semiconductor manufacturing system that includes one or more processing chambers. The semiconductor manufacturing system to form a plurality of first features on a first side of a first substrate, cover the plurality of first features with an SCL, cause a second substrate to adhere to the first substrate on a first side covered with the plurality of first features and the SCL, thin the first substrate to expose at least a subset of features of the plurality of first features, and form the one or more devices. Each device of the one or more devices includes a portion of the plurality of first features, a portion of the first substrate, and a portion of the second substrate. The SCL is selected to reduce deformation of the one or more devices.

### DETAILED DESCRIPTION

Modern technology often aims to maximize chip area utilization by manufacturing three-dimensional devices having multiple layers of semiconducting structures. For example, in NAND flash memory devices, lateral relative arrangement (CMOS near Array, or CnA) of memory cells (e.g., floating gate transistors) and peripheral transistors (e.g., CMOS circuitry used to support write/read operations with memory cells) has mostly given way to a vertical arrangement (CMOS under Array, or CuA) in which peripheral CMOS circuitry is disposed below an array of memory cells. Vertical stacking can include, e.g., stacking of logic circuitry on memory circuitry or other logic circuitry, placing interposer circuitry (interconnects) between vertically stacked dies or chips, and/or the like. Such vertical stacking can be accomplished using various hybrid bonding techniques, including bonding a first wafer supporting first features (e.g., logic/memory/circuitry) deposited thereon—to a second wafer (the wafer-to-wafer bonding process) that supports second features, aligning these second features with the first features, and then transferring the second features to the first wafer (while removing the second wafer). In other instances, one or multiple individual dies can be picked up (by a suitable end effector) from the second wafer and transferred to the first wafer by placing those individual dies in locations that accurately match locations of dies of the first wafer (the die-to-wafer bonding process). Prior to or after such feature stacking, the second wafer can be thinned (e.g., dissolved, grinded, etched, and/or polished) to expose—through the back side of the second wafer—the second features to further operations (e.g., placement of additional circuitry, dies, and/or the like). Subsequently, the aligned/transferred features and the first/second wafer can be cut into individual devices, e.g., dies or chips.

Deposition of various films and circuitry on wafers typically leads to stresses and deformation of the wafers. Such stresses result from a direct mechanical (elastic) interaction between wafers and films/circuitry, a mismatch of thermal expansion coefficients of wafer/film/conductor materials, and/or the like. Additional stress and deformation of the wafers are caused by the wafer thinning and cutting of the deposited features, and/or other processing operations (e.g., protective film/mask deposition, etc.) More specifically, thinning of the wafer leaves less material support available for anchoring (holding in place) the deposited films (and/or other features), which are subject to stresses that built up during the deposition process. As the wafer is thinned, the stress in these deposited films (and/or other features) remains largely the same and is transferred (through thinner remnants of the wafer) to the dies causing the dies and the wafer hosting the dies to deform (e.g., warp).

Die/wafer deformation can lead to misalignment of manufactured features during die-to-wafer or die-to-die transfer and can result in substandard or inoperable devices, including cracking of dies, delamination of dies, dies that fail to adhere to substrates, dies that display inconsistent electrical contacts, dies having mismatched circuitry, and/or the like. Correcting die/wafer deformation is, therefore, important for die/device quality. Furthermore, such stresses are typically local, being dependent on a specific geometry and type of features deposited at a particular locale of a wafer. This local position-dependent character of the stresses makes stress mitigation particularly challenging. Typically, when a die (e.g., a 5-30 mm die) is lifted (by an end effector) from a substrate (e.g., a carrier wafer), the die experiences a significant warping deformation. The die warping makes it very difficult to accurately match various reference die features with corresponding features deposited on a target wafer/die.

Aspects and embodiments of the present disclosure address these and other challenges of the modern semiconductor manufacturing technology by providing for systems and techniques capable of correcting die warping in die-to-die and die-to-warping bonding. In one example embodiment, die manufacturing can include multiple operations. More specifically, a first set of features (e.g., transistors, interconnect circuitry, and/or the like) can be deposited or otherwise formed on a first wafer (e.g., silicon wafer). An adhesive layer may be formed on a second wafer (e.g., a glass wafer, silicon wafer) and used to bind to the first set of features forming a structure in which the first set of features is enclosed between the two wafers. The first wafer can then undergo thinning (on its backside) until the first set of features (or a portion of the first set of features) is exposed through the backside. A second set of features (e.g., another set of memory/logic transistors and/or an interconnect circuitry) can then be formed on the exposed backside of the first wafer in such a way that the second set of features connects to the first set of features. For example, an interconnect portion of the second set of features can make contact with an interconnect portion of memory transistors of the first set of features. A protection layer can then be deposited (or otherwise formed) covering the second set of features. A suitable lifting surface (e.g., that of an electrostatic chuck) can engage the resulting stacked structure, e.g., from the side of the protection layer, and disengage the manufactured features (still bound to the thinned first wafer) from the second wafer. The resulting stacked structure can be placed on a suitable support (e.g., an adhesive tape, another wafer, etc.) that holds the stacked structure in place while the stacked structure is being cut into individual dies. The dies can then be lifted (by a suitable die-sized effector) and placed on a die carrier. The protective layer can then be removed from the dies making the dies available for any additional stacking operations, use in any chip and/or product, and/or for any further processing.

To prevent deformation and warping of dies when the individual dies are disengaged from the adhesive carrier, stresses that can occur within the stacked structure are mitigated using a stress compensation layer (SCL) deposited (or otherwise formed) at an early stage of the described process. For example, the SCL can be a film of a material type and thickness that, when deposited on the structure that includes the first wafer (prior to the thinning) and the first set of features, introduces a stress that at least partially negates the stresses caused by the first set of features. In some embodiments, the material/thickness of SCL can be selected to proactively anticipate additional stresses that will be caused (later in the process) by the second set of features, by the thinning of the first wafer (e.g., Twyman stresses), the cutting of the stacked structure into dies, and/or other manufacturing operations. Additional control of stresses in the stacked structure can be achieved with ion implantation into the SCL that modifies (often, reduces) the amount of stress in the SCL by introducing substitutions and vacancies in the crystal (or amorphous) structure of the SCL. The SCL and ion implantation can efficiently mitigate (correct) stresses that are uniform and isotropic, σₓₓ≈σ_{yy}, and also mitigate stresses that are anisotropic, σₓₓ≠σ_{yy} (herein σⱼₖ is a stress tensor).

The disclosed embodiments can be applied to correcting warping of any “wafer” or “substrate,” which refers to any material capable of supporting one or more films, masks, photoresists, layers, etc., that are deposited, formed, etched, or otherwise processed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

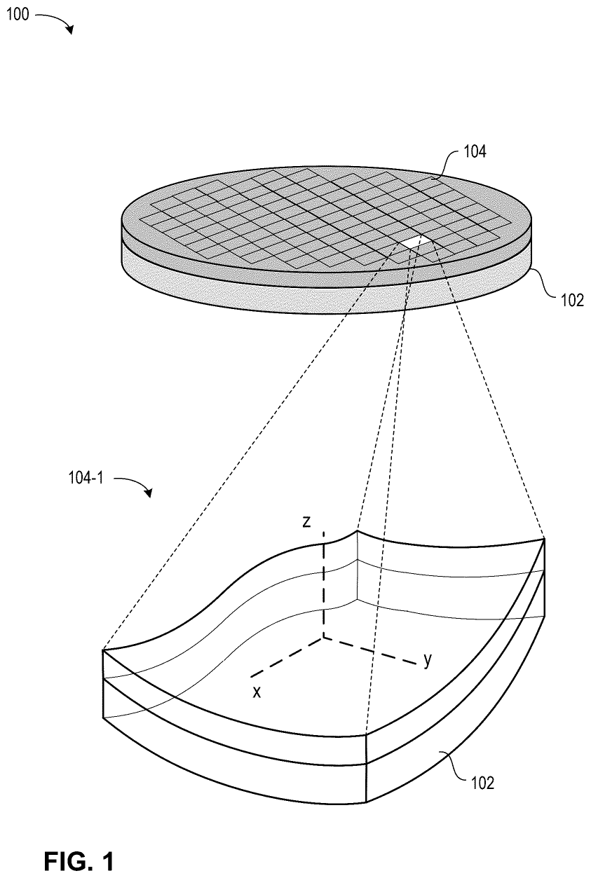

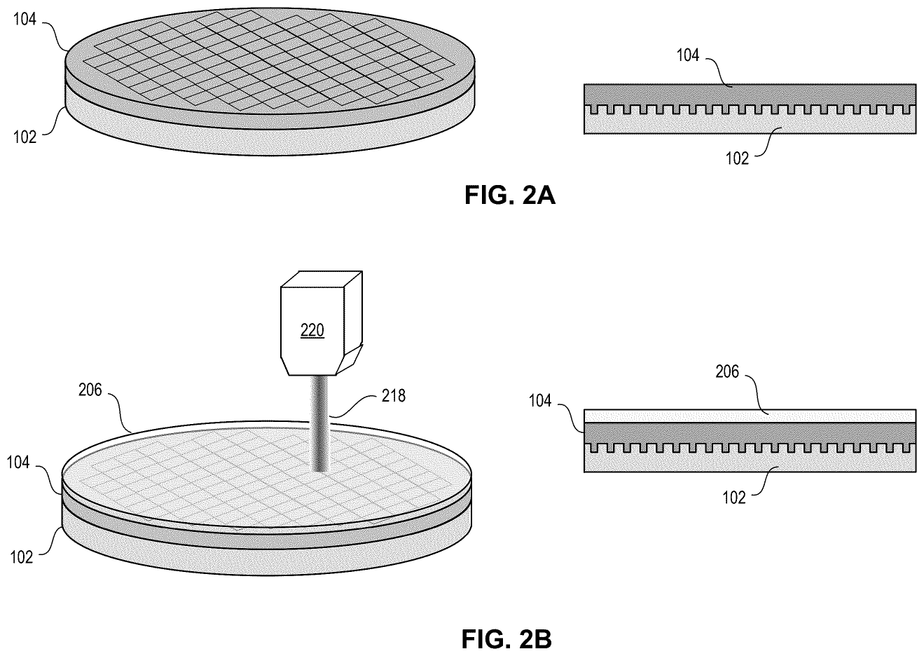

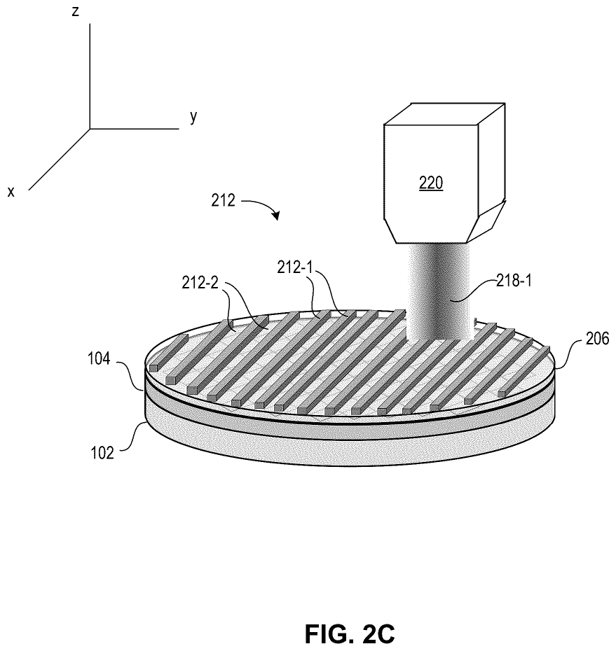

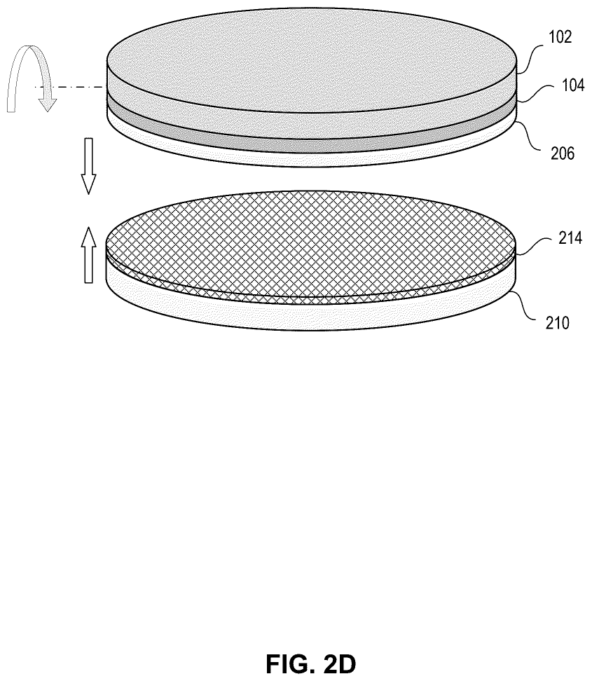

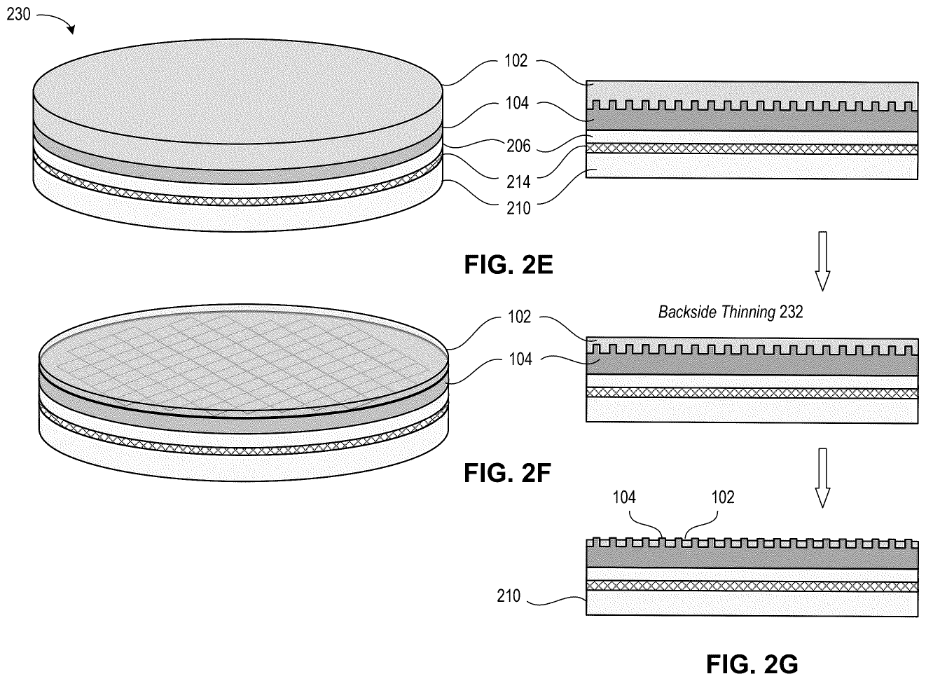

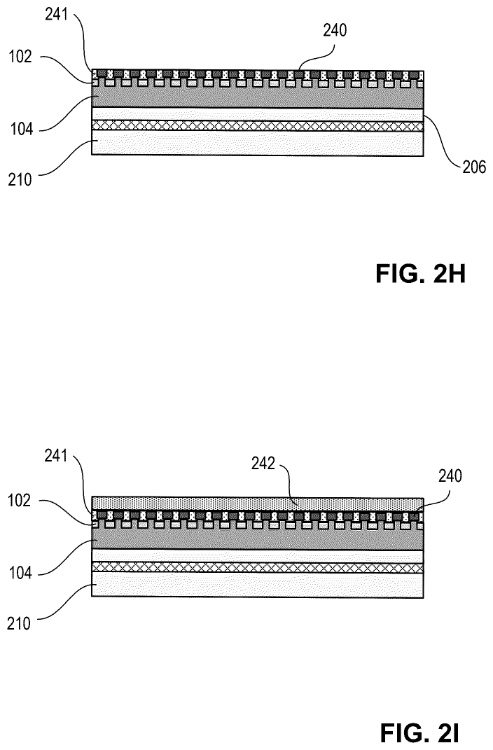

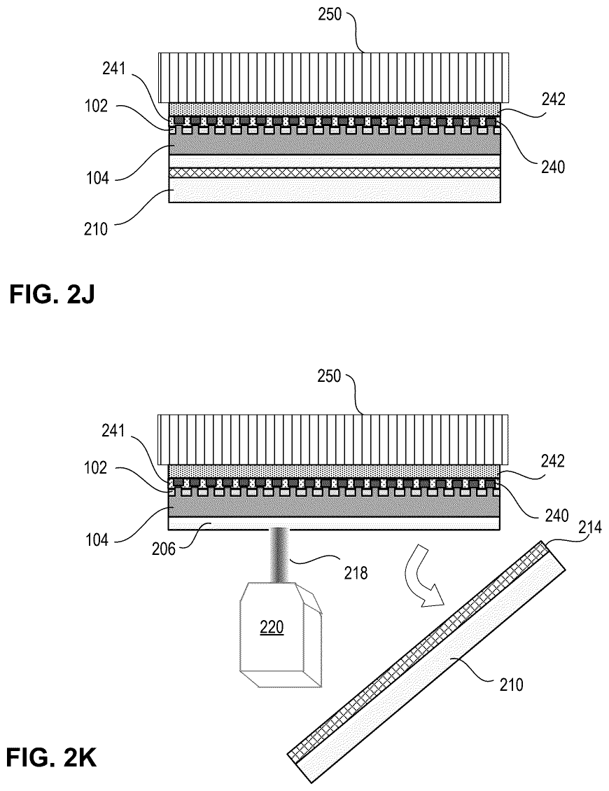

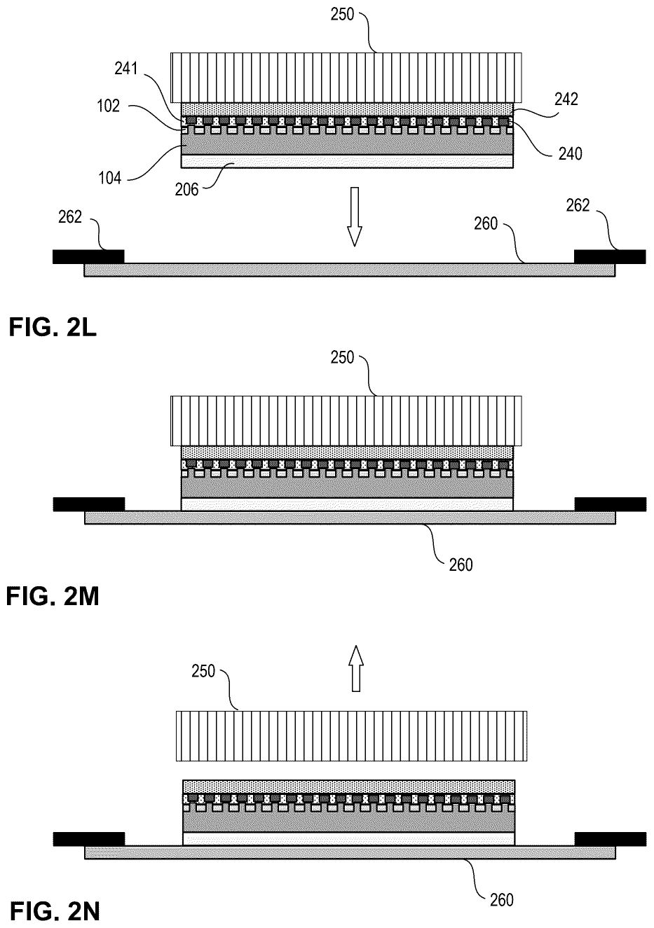

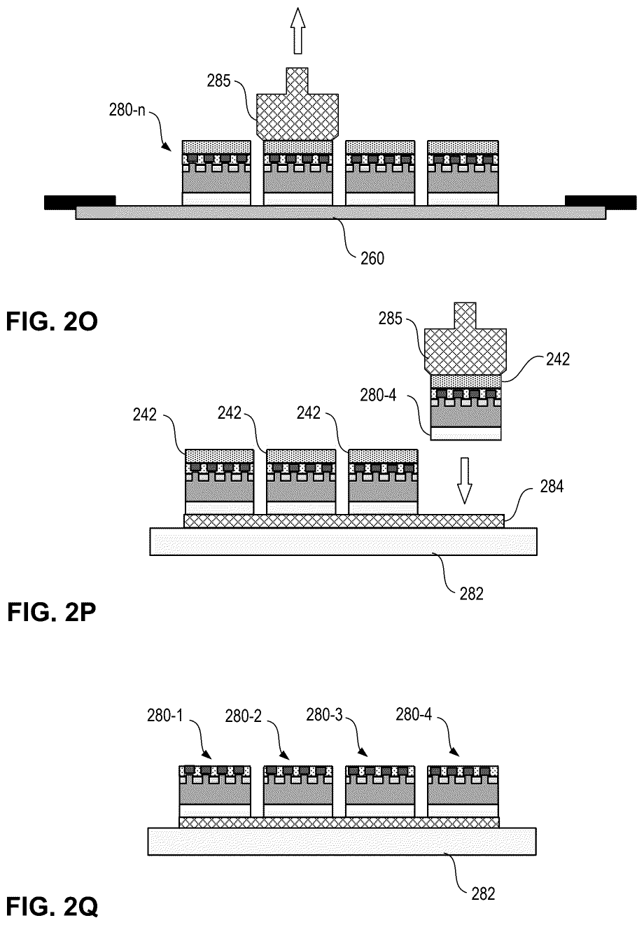

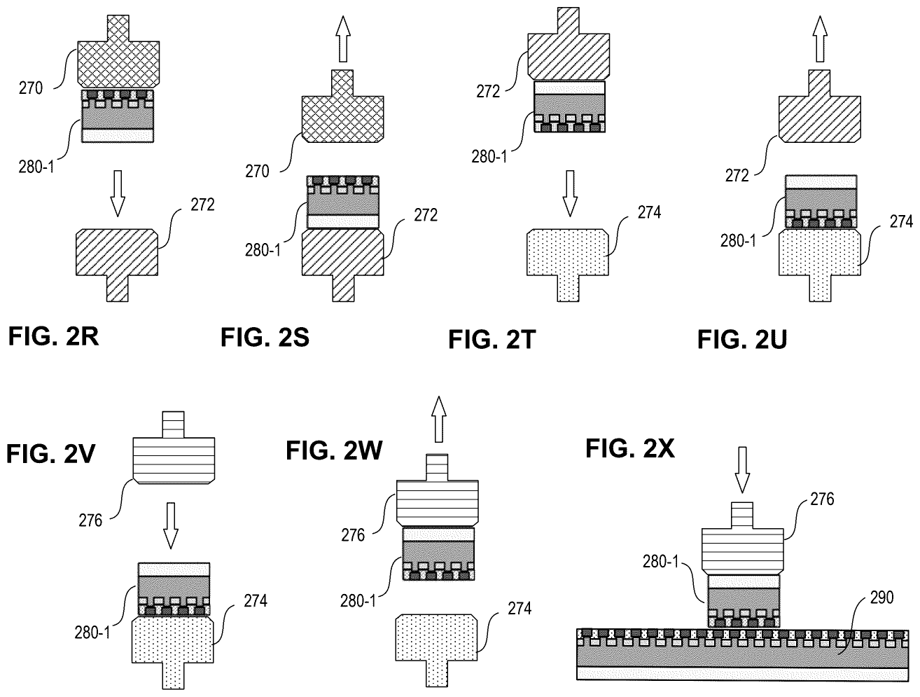

FIG. 1 illustrates schematically stresses in an example wafer structure 100 that can be mitigated using the techniques of the instant disclosure. Example wafer structure 100 includes a first wafer 102 and a first set of features 104 deposited (or otherwise formed) thereon. The first set of features 104 can include any devices (e.g., transistors, memory and/or logic) and/or additional circuitry (e.g., a wire interconnect). The exploded view in FIG. 1 further illustrates an example feature 104-1 of the first set of features 104 having a deformation. The deformation (strain) of the example feature 104-1 illustrated in FIG. 1 may not be representative of the geometry of the example feature 104-1 while the example feature 104 remains attached to wafer 102. Such a deformation can be fully revealed after the example feature 104-1 is formed into a die, e.g., using various operations illustrated in FIGS. 2A-2Q, including but not limited to deposition of second (third, etc.) set of features (not shown in FIG. 1) and/or one or more films, thinning of the first wafer 102, cutting and segmenting the formed stacked structure (that includes wafer 102, the first set of features 104, and/or any additional deposited materials) into individual dies, and/or the like. Prior to transforming wafer structure 100 into individual dies, wafer structure 100 can have a smaller (than illustrated in FIG. 1) deformation but a substantial stress. To prevent this stress from causing a deformation upon cutting of the first set of features 104 into individual dies, the stress can be corrected using one or more techniques disclosed below.

More specifically, existing deformation of wafer 102 (with the first set of features 104 deposited thereon) can be measured (e.g., using optical measurements techniques) and parameters for an optimal SCL can be selected, including SCL's material, thickness, and/or the like. For example, the SCL can be selected to have a tensile or compressive stress. Although different portions of wafer 102 can have tensile stress (σⱼₖ>0), other portions of wafer 102 can have compressive stress (σⱼₖ<0), while yet other portions can have anisotropic (saddle-like) stress (e.g., σₓₓ>0, σ_{yy}<0), type and thickness of the SCL can be selected so that the sign of the stress is the same throughout the wafer/features/SCL stack.

Further stress mitigation includes applying an ion (electron, photon) beam to the SCL to modify (e.g., reduce) stress in the SCL to a desired level. Parameters of an ion (or other particles/waves) implantation map (a distribution of local doses of ion implants) n(x, y) can be computed to reduce the local stress in the wafer σⱼₖ(x, y) to a degree that brings the shape of the wafer to a flat (or nearly flat) shape. A number of techniques can be used for determining an optimal ion implantation map.

The stress-modulation beam can include matter particles (e.g., ions, electrons), electromagnetic waves (e.g., UV light, visible light, infrared light, etc.), and/or a suitable combination thereof. The stress-modulation beam strikes the SCL and changes the bonding network of the SCL. For example, the stress-modulation beam of low energy may interact with surface atoms of the SCL, e.g., removing some of the surface atoms, effectively implementing etching of surface regions of the SCL. The effectiveness of such etching can be controlled by a choice of ion species/radicals/ambient gasses. In another example, the stress-modulation beam of high energy can deposit ions inside the SCL. Particles and/or photons of the beam can break bonds of the bonding network (or crystal lattice) of the SCL forming vacancies therein, and can further cause annealing due to local heating, UV curing, and/or other effects. Substitution defects and/or vacancies created by the particles of the stress-modulation beam modify (e.g., reduce) stress in the SCL and, through the SCL, in the wafer. The intensity and/or dose (the intensity integrated over time) of the stress-modulation beam can vary with a location within the SCL and can be determined (e.g., simulated, modeled, etc.) in a way that maximally relieves the stress in the SCL (and, further, in the wafer). This causes the combination of the wafer, the deposited features/films, and the SCL to flatten and facilitates precise alignment of features that are patterned on the wafer, etched in one or more stacks of layers, and/or the like, and improves quality of the manufactured devices. The intensity/doses of irradiation can be determined based on the measured deformation of the wafer. Multiple techniques can then be used to determine optimal intensity and/or dose of the stress-modulation beam, such as Monte Carlo simulations, influence function computations, and/or other techniques, as disclosed below.

Stresses σⱼₖ(x, y) that can be mitigated using these techniques include, but are not limited to, stresses that occur in the first wafer globally, as a result of film deposition, global wafer thinning, polishing, cleaning, and/or the like. The mitigated stresses can further include stresses that occur in the wafers because of patterning of the wafers, e.g., deposition of features on the wafers, cutting of the wafers (with the stacked structure placed thereon), and/or the like. The stresses σⱼₖ(x, y), if left unmitigated, would result—upon cutting the stacked structure into individual dies and lifting the dies off a support surface—in a deformation (strain) of one or more of the following types. For example, deformations can include a deformation W₁(x, y) from global film deposition, wafer thinning/polishing/cleaning, and/or the like, a deformation W₂(x, y) from wafer patterning with various features, cutting of the wafer, and/or the like, and a die-specific deformation W₃(x, y) that depends on the specific location of the die on the wafer (e.g., near the center of the wafer, closer to the edge of the wafer, etc.). According to Hooke's law, deformations W₁, W₂, W₃, etc., which occur after die segmentation/lifting, can be proportional to the stresses σⱼₖ(x, y) that existed prior to the segmentation/lifting. To relate deformations W₁, W₂, W₃ to stresses σⱼₖ(x, y), a wafer (e.g., the first wafer) with various features (e.g., the first/second sets of features, SCL, and/or various other films, such as protection films) can be modeled using a plate theory of elastic media. The techniques for determining stresses and deformations can include numerical solution of the elastic plate equations, finite difference methods, influence function (Green's function) techniques, and/or the like. In some embodiments, the second waver can have low deformation/stress, e.g., by virtue of not hosting patterned structures (and serving as a carrier wafer).

Advantages of the disclosed embodiments include but are not limited to correcting deformations of die-forming wafers to prevent die warping during die-to-die and/or die-to-wafer semiconductor manufacturing for more accurate alignment of die features.

A “wafer,” as used herein, refers to any substrate or material surface formed on a substrate upon which film processing is performed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

FIGS. 2A-2X illustrate a process of die-to-die and/or die-to-wafer semiconductor manufacturing that deploys stress-compensation layers, according to at least one embodiment. FIG. 2A shows a sample that includes wafer 102 supporting a first set of features 104. In some embodiments, wafer 102 may have previously undergone any additional treatment, such as annealing. The left depictions in FIG. 2A and FIG. 2B illustrate perspective view of wafer 102 (and features deposited thereon) while the right depictions are frontal views of the same structures. First set of features 104 can include source lines of NAND devices, stacks of memory and/or logic transistor layers, interconnect circuitry, uniform (unpatterned) films, patterned films, die boundaries, chip boundaries, area boundaries, slits, channels, and/or any other applicable features. Features 104 can be deposited (or otherwise formed) using atomic layer deposition techniques, photolithography techniques, etching techniques, chemical-mechanical polishing (CMP) techniques, and/or any other techniques.

As illustrated in FIG. 2B, a stress compensation layer (SCL) 206 can be deposited (or otherwise formed) on the front side of wafer 102 covering features 104. SCL 206 can be deposited using chemical vapor deposition (CVD) techniques, in some embodiments. In some embodiments, SCL 206 can be made from silicon nitride Si₃N₄ or some other material whose stress can be efficiently controlled during deposition of SCL 206. The level of stress in SCL 206 can be set at SCL 206 deposition by controlling conditions in the processing chamber during deposition of SCL 206, including but not limited to concentration of argon and/or nitrogen atoms (ions) in the environment of the processing chamber, voltage, temperature, and/or the like. In some instances, SCL 206 can have a tensile stress while, in other instances, SCL 206 can have a compressive stress. The type of SCL (tensile vs. compressive) can be determined by a (measured and/or inferred) sign of stress in wafer 102 prior to the SCL deposition. Similarly, the magnitude of stress of SCL 206 can be determined (measured and/or inferred) based on a magnitude of stress in wafer 102.

As further illustrated in FIG. 2B, a stress-modulation beam 218 can be applied to SCL 206 to deliver a position-dependent dose of particles (e.g., ions or electrons) and/or photons n(x, y), where x, y are in-plane coordinates within the wafer/SCL plane. Stress-modulation beam 218 can be generated by a suitable collimating and focusing column 220. Application of stress-modulation beam 218 causes stress in the sample that contains wafer 102, features 104, and SCL 206 to decrease, resulting in the flattening of the sample (reduced deformation).

FIG. 2B illustrates a narrow (e.g., 1-10 μm in diameter or even less than 1 μm) stress-modulation beam 218 capable of imparting a high-resolution dose n(x, y). In other embodiments, as illustrated in FIG. 2C, a position-dependent dose n(x, y) can be imparted using a wide stress-modulation beam 218-1 and a patterned (spatially-modulated) mask 212 deposited or otherwise formed on SCL 206. In some embodiments, patterned mask 212 can include raised portions 212-1 (e.g., ridges, protrusions, elevations, etc.) and recessed portions 212-2 (e.g., trenches, grooves, ruts, dips, etc.). Patterned mask 212 modulates the amount of irradiation that reaches SCL 206. For example, the portions of SCL 206 that are located below raised portions 212-1 of directional patterned mask 212 (protected areas) may be shielded to a higher degree than the portions of SCL 206 that are located below recessed portions 212-2 (stress-mitigated areas).

FIG. 2C shows a directional pattern having a characteristic length scale along one direction (e.g., x) substantially exceeding a characteristic length of the features along the other direction (e.g., y). An example directional pattern can include diffraction gratings with a pitch of 10 nm-100 μm or more and length of lines of 10 μm-1 cm or more. The patterned mask 212 illustrated in FIG. 2C can partially screen SCL 206 from stress-modulation beam 218-1 to impart a unidirectional dose n (x) to SCL 206 to efficiently correct a cylindrical deformation (e.g., left after deposition of SCL 206 removes bow-like deformation of wafer 102). In other embodiments, the patterned mask 212 can be bidirectional (not shown in FIG. 2C) causing stress-modulation beam 218-1 to impart a dose n(x, y) that is modulated along both (x and y) directions. In some embodiments, patterned mask 212 can be made of a different material than SCL 206. For example, patterned mask 212 can be or include a photoresist mask deposited on SCL 206. In some embodiments, patterned mask 212 can be made of the same material as SCL 206. In some embodiments, patterned mask 212 can be etched in SCL 206.

In some embodiments, a material of SCL 206, a thickness of SCL 206, a target stress of the SCL, and/or settings of stress-modulation beam 218 can be determined in view of an estimated (e.g., predicted) deformation caused by various processing operations (e.g., deposition, etching, cutting, and/or the like) being performed to manufacture one or more devices (e.g., semiconductor devices). Estimated (in contrast to presently measured) deformation can take into account one or more operations that are yet to be performed, e.g., to proactively anticipate and mitigate deformation that occurs after the SCL 206 is formed and the stress-modulation beam 218 is applied thereto.

As illustrated in FIG. 2D, first wafer 102 (with features 104 and SCL 206) can be rotated with first wafer 102 facing up and bonded with a second wafer 210. Second wafer 210 can be a glass wafer (e.g., SiO₂ wafer), a silicon wafer, a corundum wafer, and/or any other suitable type of wafer. Bonding of first wafer 102 to second wafer 210 can be facilitated by any suitable adhesion layer 214, e.g., a polyimides layer, a spin-on glass layer, a photoresists, and/or the like. In some embodiments, in lieu of the adhesion layer 214, a fusion bonding may be performed to bond first wafer 102 to second wafer 210.

FIG. 2E depicts a bonded product 230 in which first wafer 102 and second wafer 210 enclose first features 104, SCL 206, and adhesion layer 214 (and can further enclose any additional layers, films, patterns, and components). (FIGS. 2E-2F illustrate both the perspective views of the product and its cross-sectional views.)

As illustrated in FIG. 2F and FIG. 2G, first wafer 102 can undergo backside thinning 232 until the first set of features 104 (or a portion of the first set of features) is exposed through the backside of the first wafer 102 (FIG. 2G). Backside thinning can include grinding, CMP, wet etching, dry etching, polishing, and/or the like. In some embodiments, exposing the first set of features can include forming Through-Silicon VIA (vertical electrical connection). As illustrated in FIG. 2H, a second set of features 240 can be formed on the exposed (revealed) backside of the first wafer 102 together with a (redistribution) dielectric layer 241. For example, dielectric layer 241 may electrically insulate, from each other, various features of the second. In some embodiments, second set of features 240 connects (including electrical connection) to first set of features 104. The second set of features 240 can include additional memory and/or logic transistors, other conducting or semiconducting devices, interconnect circuitry, and/or the like, or some combination thereof. The surface of dielectric layer 241 may be level with the top of the second set of features 240, as illustrated. In some embodiments, the second set of features 240 can be a conducting (e.g., copper) bonding pad, and/or the like. In particular, an interconnect portion of the second set of features 240 can make electrical contact with an interconnect portion of transistors of the first set of features 104.

As illustrated in FIG. 2I, a protection layer 242 can then be deposited (or otherwise formed) covering the second set of features 240 and dielectric layer 241. The protection layer 242 can include a polymer film, a carbon layer, an oxide layer, and/or some other protection layer that can be removed (during a later processing stage) without damage to the underlying structure (e.g., the first set of features 104, the second set of features 240, and/or other parts of the structure).

As illustrated in FIG. 2J, a suitable effector 250, e.g., electrostatic chuck, a suction effector, and/or the like, can engage the surface of the sample, e.g., on the side of the protection layer 242. As illustrated in FIG. 2K, effector 250 can mechanically separate (debond) the second wafer 210 (with or without the adhesion layer 214) from the remaining portion of the structure, e.g., from first wafer 102, first set of features 104, second set of features 240, SCL 206, and/or other components, as can be applicable. As further illustrated in FIG. 2K, debonding of the second wafer 210 exposes SCL 206. Accordingly, in some embodiments, irradiation of SCL 206 with the stress-modulation beam 218 can be performed after the second wafer 210 debonding rather than (or in addition to) after SCL is deposited (e.g., as illustrated in FIG. 2B or FIG. 2C).

As illustrated in FIG. 2L, effector 250 can transport the sample to a suitable receiving surface 260, which can be an adhesive tape, another wafer, or some other surface capable of securely holding the structure. The receiving surface 260 can be secured in place by a support structure 262, e.g., a support ring attached to the adhesive tape. After placing the sample on the support surface (FIG. 2M), effector 250 can disengage from the sample (FIG. 2N), e.g., by turning off the electric voltage that attracts the sample to effector 250.

As illustrated in FIG. 2O, the sample held in place by the receiving surface 260 can be cut into individual dies 280-n. The dies 280-n can be lifted from the receiving surface 260 by a suitable die-sized effector 285. The dies 280-n can then be placed on a die carrier 282. In some embodiments, the dies 280-n can be held on die carrier 282 using an adhesion layer 284 (FIG. 2P). In some embodiments, adhesion layer 284 can be absent and the dies 280-n can rest directly on die carrier 282 without bonding to die carrier 282. As illustrated in FIG. 2Q, the protective layer 242 can be removed from the dies 280-n making the dies available for any additional manufacturing operations, such as surface activation, hydrophilization, etc., and/or for use in any chip and/or product. In some embodiments, deformation (strain) in one or more dies 280-n can be measured, e.g., using various optical inspection techniques, to determine residual deformation and a degree to which stress compensation has been successful.

In some embodiments, the process of die manufacturing can include collective die-to-wafer bonding. In such embodiments, a dielectric can be deposited between dies 280-n as well as on top of dies 280-n with the excess of the dielectric removed, e.g., using CMP or other removal techniques, to re-expose the features of the dies 280-4. The carrier wafer 282 can then be flipped and dielectric-separated dies 280-n can be bonded to another wafer (not shown in FIG. 2Q), all dies 280-2 bonded at the same time.

In some embodiments, the process of die manufacturing can include sequential die-to-wafer bonding. In particular, as illustrated in FIGS. 2R-2X, individual dies can be transferred—one by one—to another wafer structure 290. More specifically, end effector 270 can pick up one of the dies, e.g., die 280-1, from wafer carrier 282 (with reference to FIG. 2Q) and place die 280-1 (with the features of die 280-1 facing up) on another end effector 272, as shown in FIGS. 2R-2X. End effector 272 and die 280-1 can be rotated, as shown in FIG. 2T, and placed (with the features of die 280-1 facing down) on yet another end effector 274, as shown in FIG. 2U. A final end effector 276 (e.g., a vacuum or pneumatic end effector) can lift die 280-1 off end effector 274, as shown in FIGS. 2V-2W, and deliver die 280-1 to wafer structure 290, as shown in FIG. 2X. The wafer structure 290 can have any features deposited (or otherwise formed) thereon and end effector 276 can effectuate placement and bonding of die 280-1 to wafer structure 290 such that the features of die 280-1 properly align with the features of wafer structure 290.

In some embodiments, prior to irradiating SCL 206 with stress-modulation beam 218, the amount of stress in wafer 102 (with films and mask deposited thereon) can be determined by measuring a profile h(\vec{r}) of wafer 102. The profile h(\vec{r}) can refer to the vertical coordinate of the bottom surface of wafer 102. In some instances, stress in wafer 102 can be uniform and isotropic, σₓₓ≈σ_{yy}. In some instances, stress in wafer 102 can be anisotropic, σₓₓ≈σ_{yy}. Certain feature patterns can result in stresses that are tensile along one direction, e.g., σₓₓ>0, and compressive along a perpendicular direction, σ_{yy}<0, resulting in saddle-shaped wafers. Such saddle-shaped features can arise, for example, in stacks of materials with directional patterning, e.g., patterning of wordlines in NAND devices.

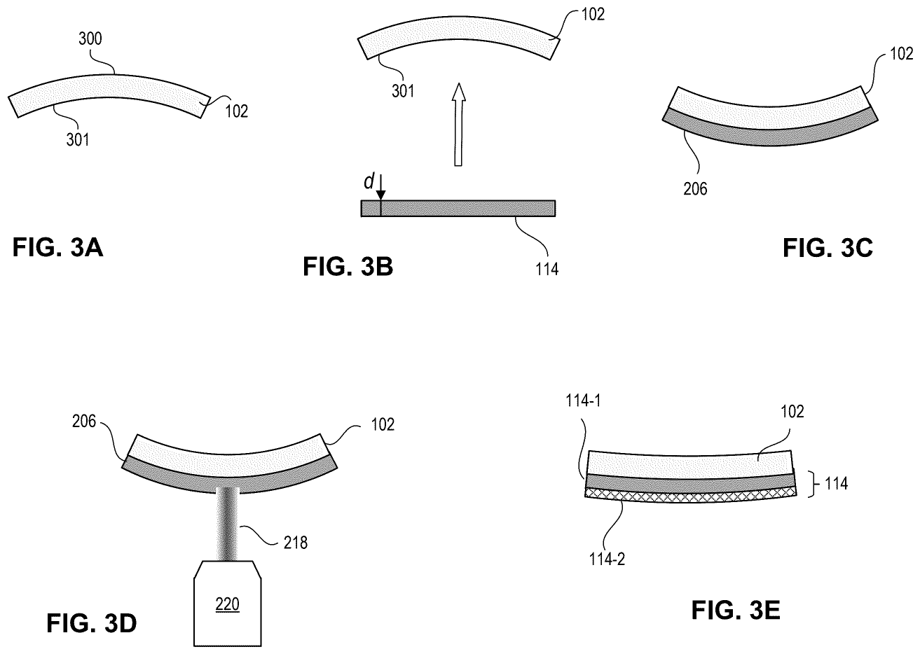

In some embodiments, a vertical profile of wafer 102 deformation z=h(\vec{r}) can be measured using optical metrology (e.g., optical interferometry) techniques. In some embodiments, wafer deformation z=h(\vec{r}) can be measured after a stack 104 of layers/films is deposited on wafer 102. The wafer profile h(\vec{r}) can then be represented via a number of parameters that qualitatively and quantitatively characterize geometry of the wafer deformation, e.g., a set of Zernike (or a similar set of) polynomials, h(\vec{r})=ΣⱼAⱼZⱼ(\vec{r}). Consecutive coefficients A₁, A₂, A₃, A₄ . . . represent weights of specific geometric features (elemental deformations) of wafer 102 described by the corresponding Zernike polynomials Zⱼ(\vec{r}). In some embodiments, a material of SCL 206 mask can be selected based on the sign of a paraboloid bow coefficient A₄. In some embodiments, selection of a thickness d of SCL 206 can be made based on a value of the paraboloid bow coefficient A₄. As illustrated in FIGS. 3A-3E, thickness d of SCL 206 can be selected to overcorrect the wafer deformation to some degree. The overcorrection can be chosen in conjunction with a type of stress-modulation beam 218 (e.g., ion implants, photons, electrons, etc.), a type of implant species, energy, and dose to ensure maximum effect from the stress mitigation. Stress in the combined structure of the wafer, films, and SCL 206 can then be modified by stress-modulation beam 218 that strikes SCL 206 and changes its crystal (or amorphous) structure. Substitution defects and/or vacancies created by beam 218 mitigate (e.g., reduce) stress in SCL 206 and can reduce the degree of stress overcorrection caused by SCL 206 deposition. This causes the wafer to flatten.

FIGS. 3A-3E illustrate schematically a process of correcting a wafer deformation using a stress-modulation beam applied to the back side of a wafer, according to at least one embodiment. FIG. 3A depicts wafer 102 having a deformation, which can include a paraboloid bow deformation (with negative coefficient A₄<0, as illustrated) and can further include other deformations, including saddle deformation, residual deformation, etc. The wafer's front side 300 can include any number of features, e.g., the first set of features 104 (as illustrated with FIGS. 2A-2Q), deposition and/or etching patterns, a stack of layers/films, and/or any other structures. FIG. 3B illustrates deposition of SCL 206 on the back side 301 of wafer 102. SCL 206 can be (or include) a silicon nitride layer or some other type of material. In some embodiments, SCL 206 can include layers of multiple materials. In some embodiments, a material of SCL 206 can be selected in view of the sign of coefficient A₄. For example, for a negative bow, A₄<0, SCL 206 can be selected to have a compressive stress (as illustrated in FIGS. 3B-3E). Conversely, for a positive bow, A₄>0, SCL 206 can be selected to have a tensile stress. SCL 206 can be deposited using any suitable deposition techniques including physical vapor deposition (e.g., sputtering), chemical vapor deposition (e.g., plasma-assisted deposition), epitaxy, exfoliation, and/or the like. SCL 206 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, thickness d of SCL 206 can be selected to overcorrect the wafer deformation to some degree, e.g., as illustrated in FIG. 3C where a negative paraboloid is overcorrected to a positive paraboloid bow. The thickness-dependent paraboloid bow correction A_{corr}(d) changes wafer deformation from h(r, ϕ) to h_{corr}(r, ϕ):

$${h}_{corr} ( r , ϕ ) = h ( r , ϕ ) + {A}_{corr} ( d ) \cdot {Z}_{4} ( r , ϕ ) .$$

The degree of overcorrection can be chosen in conjunction with a type and parameters (e.g., energy, dose, etc.) of a specific stress-modulation beam 218 to be used on SCL 206. The overcorrection can make the combined structure of wafer 102 and SCL 206 susceptible to further control of stress (and thus control of deformation of the wafer h_{corr}(r, ϕ)). As illustrated in FIG. 3D, collimating and focusing column 220 can generate a stress-modulation beam 218 that strikes SCL 206 and changes its elastic properties, e.g., by creating vacancies, breaking crystal bonds, depositing ions, and/or via any other applicable mechanisms. Stress-modulation beam 218 can carry photons, electrons, silicon ions, phosphorus ions, argon ions, neon ions, xenon ions, krypton ions, and/or the like. In some embodiments, the energy and type of ions in stress-modulation beam 218 can be selected to limit the implanted ions to the volume of SCL 206 without allowing the ions to reach wafer 102 (and/or any layers/films deposited on wafer 102). Ions that lodge in SCL 206 create substitution defects therein. Additionally, the ions leave a trail of vacancy defects along paths of propagation in SCL 206. The substitution defects and/or vacancies mitigate (e.g., reduce) stress in SCL 206 and can reduce the degree of stress overcorrection caused by the SCL deposition. This causes the combination of wafer 102 and SCL 206 to flatten.

In some embodiments, the number of ions ΔNᵢ deposited per small area ΔA=ΔxΔy (or the total amount of photon energy applied to this area) of wafer 102 can be determined using simulations (performed as described in more detail below) based on the local value of the corrected deformation h_{corr}(r, ϕ), which may include a saddle deformation, a residual deformation, and the part of the paraboloid bow deformation A_{corr}(d)+A₄ that has been overcorrected by the deposition of stress-compensation layer 218. The target local density n(x, y)=ΔNᵢ/ΔxΔy of the ions can be delivered by controlling the scanning velocity v of stress-modulation beam 218. In some embodiments, stress-modulation beam 218 has a profile that can be approximated with a Gaussian function, e.g., the ion flux j(ρ)=j₀ exp(−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that includes the following number of ions:

$$\frac{Δ {N}_{i}}{Δ x Δ y} = \frac{{j}_{0}}{v} {\int }_{- ∞}^{∞} dx {e}^{- {x}^{2} / {a}^{2} - {y}^{2} / {b}^{2}} = \frac{{j}_{0} \sqrt{π}}{va} {e}^{- {y}^{2} / {b}^{2}} .$$

Correspondingly, by reducing the scanning velocity v, the number of ions received by various regions of SCL 206 can be increased, and vice versa. Additionally, stress-modulation beam 218 can perform multiple scans with different offsets y so that various points of SCL 206 receive multiple doses of ions with different factors e^{-y}^{²}^{/b}^{²} that can average to a target dose. For example, after n passes of stress-modulation beam 218, each made with a respective velocity vₖ at a different distance yₖ from the center of the beam to the area ΔxΔy, the total dose of ions (or amount of electromagnetic radiation) received by this area will be

$${n ( x , y ) = \frac{Δ {N}_{i}}{Δ x Δ y} \vert}_{total} = {j}_{0} \sqrt{π} {\sum }_{k = 1}^{n} \frac{{e}^{- {y}_{k}^{2} / {b}^{2}}}{{av}_{k}} .$$

As illustrated in FIG. 3E, a stress-mitigated portion 114-2 of SCL 206 results in a significant mitigation of deformation of wafer 102, including saddle and residual deformations (the remaining portion 114-1 of SCL 206 may be unmitigated or weakly mitigated and may include deeper regions o SCL 206 with little exposure to stress-modulation beam 218).

In some embodiments, the intensity and/or total amount of irradiation per various areas of wafer 102 can be determined using simulations, e.g., Monte Carlo simulations. The Monte Carlo simulations can be performed for a film made of the actual material used in SCL deposition and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to SCL 206 (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of masks/layers, angles of particle incidence on the films, and/or the like.

In some embodiments, the implantation map n(\vec{r}) can be computed using an influence function G(\vec{r}; \vec{r}) that characterizes a response (e.g., deformation) at a point \vec{r} of the wafer as caused by a point-like force applied at another point \vec{r}′ of wafer 102. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, wafer deformation h(\vec{r})=h_{quad}(\vec{r})+hᵣₑₛ(\vec{r}) can be represented (decomposed) as a combination of a quadratic h_{quad}(\vec{r}) and residual (non-quadratic) hᵣₑₛ(\vec{r}) contributions. The quadratic deformation can include a parabolic (paraboloid) part hₚₐᵣ(\vec{r}), which has the complete axial symmetry, and a saddle part h_{saddle}(\vec{r}). The thickness d of SCL 206 can be computed (or empirically determined) in such a way that the mask is to apply a desired target stress to wafer 102. To eliminate a non-uniform saddle deformation, SCL 206 can be of such thickness/material that turns the saddle deformation into a cylindrical deformation having a definite sign throughout the area of wafer 102. The uniform-sign cylindrical deformation (as well as a residual higher-order non-quadratic deformation) can then be mitigated with irradiation by stress-modulation beam 218. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of SCL 206 (e.g., type and thickness) while the remaining cylindrical deformation (and the higher-order residual deformation) can be addressed by appropriately selected ion or photon irradiation doses n (+).

In some embodiments, mitigation of a cylindrical deformation or a saddle deformation can include identifying principal axes (directions) of the cylinder/saddle and a magnitude of the cylindric/saddle deformation and directing stress-modulation beam 218 into appropriately selected edge regions of SCL 206. For example, individual edge regions to which the beam 218 is directed can have a width that is at or below 30% of a diameter of wafer 102. Residual higher-order (ripple) deformations can then be mitigated with further irradiation into the area of SCL 206.

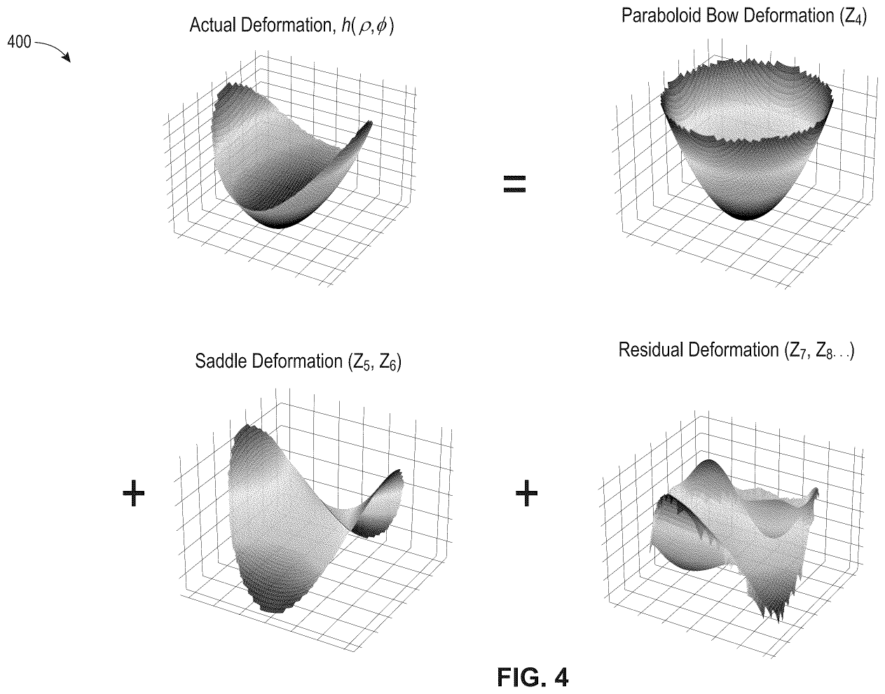

Some of these techniques will now be described in more detail. In one embodiment, a vertical profile of wafer deformation z=h(\vec{r}) can be measured using optical metrology techniques. For example, an interferogram of the profile h(\vec{r}) can be obtained using optical interferometry measurements. The wafer profile h(\vec{r}) can then be represented via a number of parameters that qualitatively and quantitatively characterize geometry of the wafer deformation. In some embodiments, a set of Zernike (or a similar set of) polynomials may be used to represent the wafer profile,

$$h ( \vec{r} ) = {\sum }_{j} {A}_{j} {Z}_{j} ( \vec{r} ) ,$$

where the planar radius-vector \vec{r}=(r, ϕ) may be represented as the radial coordinate r and the polar angle ϕ within the (average) plane of the wafer. Consecutive coefficients A₁, A₂, A₃, A₄ . . . represent weights of specific geometric features (elemental deformations) of wafer 102 described by the corresponding Zernike polynomials Z₁(r, ϕ), Z₂(r, ϕ), Z₃(r, ϕ), Z₄(r, ϕ) . . . . (Herein, the Noll indexing scheme for the Zernike polynomials is being referenced.) The first three coefficients are of less interest as they describe a uniform shift of wafer 102 (coefficient A₁, associated with the Z₁(r, ϕ)=1 polynomial), a deformation-free x-tilt that amounts to a rotation around the y-axis (coefficient A₂, associated with the Z₂(r, ϕ)=2r cos ϕ polynomial), and a deformation-free x-tilt that amounts to a rotation around the x-axis (coefficient A₃, associated with the Z₃(r, ϕ)=2r sin ϕ polynomial) that can be eliminated by a realignment of the coordinate axes. The fourth coefficient A₄ is associated with Z₄(r, ϕ)=\sqrt{3}(2r²−1) and characterizes an isotropic paraboloid deformation (“bow”). The fifth A₅ and the sixth A₆ coefficients are associated with Z₅(r, ϕ)=\sqrt{6}r² sin 2ϕ and Z₆(r, ϕ)=\sqrt{6}r² cos 2ϕ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation h(r, ϕ) along the radial direction, along the azimuthal direction, or both and collectively represent a residual deformation, hᵣₑₛ(r, ϕ)=h(r, ϕ)−Σⱼ₌₄⁶AⱼZⱼ(r, ϕ). FIG. 4 illustrates an example Zernike polynomial decomposition 400 of one actual deformation h(r, ϕ) (top left) of a wafer (e.g., wafer 102), in arbitrary units, into a paraboloid bow deformation A₄Z₄(r, ϕ) (top right), a saddle deformation A₅Z₅(r, ϕ)+A₆Z₆(r, ϕ) (bottom left), and a residual deformation, hᵣₑₛ(r, ϕ) (bottom right), according to at least one embodiment.

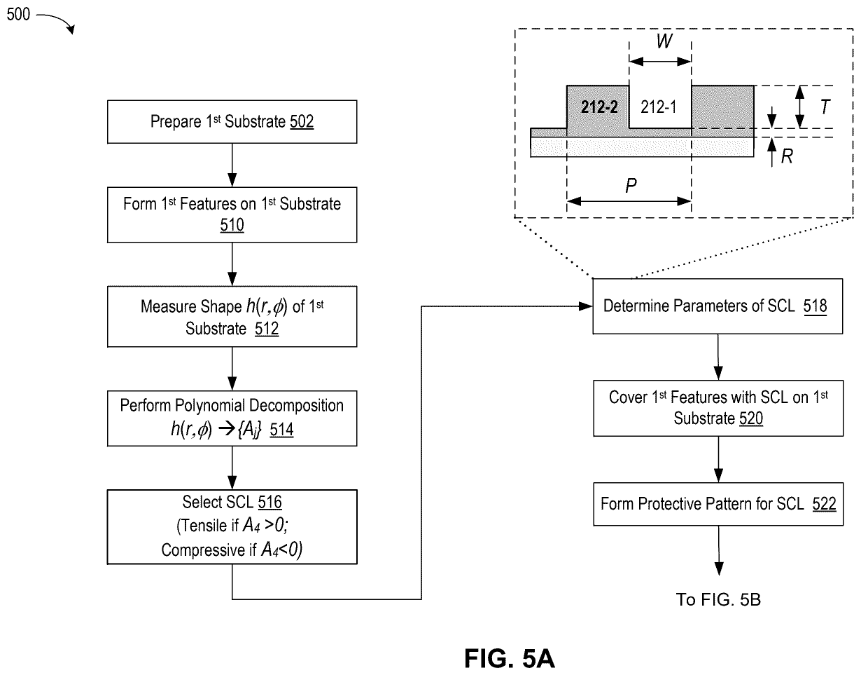

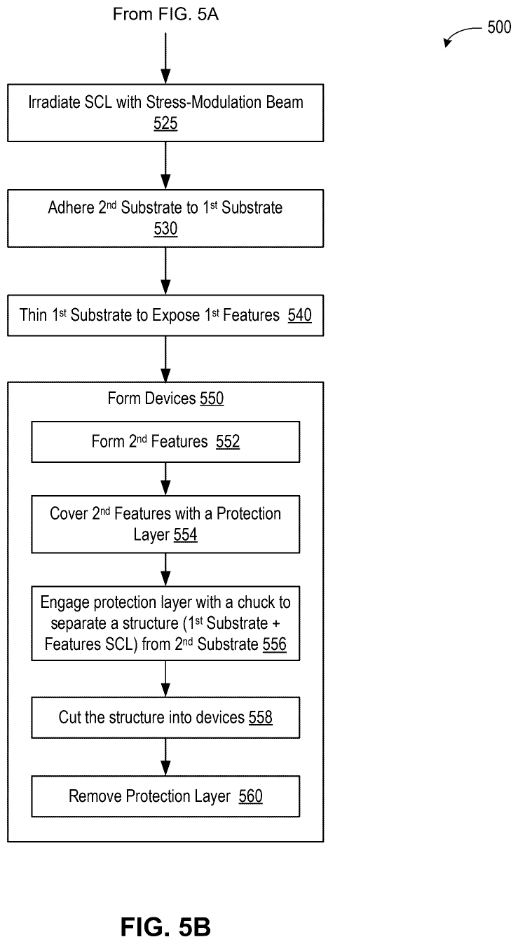

FIG. 5A-5B are flowcharts illustrating an example method 500 of mitigation of wafer stress and deformation using stress-compensation beams, in accordance with at least one embodiment. Method 500 can be performed to manufacture one or more semiconductor devices using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle wafers, e.g., moving wafers into and out of processing chambers. The transfer chamber can further be connected to a load-lock chamber (Front-End Interface) that can be coupled to one or more Front Opening Unified Pod carriers that hold bare wafers, processed wafers, partially processed wafers, and/or the like. Operations performed by the semiconductor manufacturing system, including any, some or all operations of method 500, can be performed responsive to instructions issued by a suitable computing device having a processing logic and memory to store the instructions.

At block 502, method 500 can include preparing a first substrate (e.g., wafer 102 in FIG. 2A), including but not limited to obtaining a bare substrate, preprocessing the bare substrate, e.g., polishing the substrate, removing stains and/or residue from the substrate, and/or performing any number of similar operations. At block 510, method 500 can continue with forming a plurality of first features (e.g., features 104 in FIG. 2A) on a first side of a first substrate. The first features can include any number of patterns, layers, films, slits, masks, holes, and/or the like. For example, the features can include one or more layers of conducting material(s), which can include interconnect circuitry, transistors, and/or the like. In some embodiments, the features can include oxygen layers, nitrogen layers, silicon layers, germanium layers, silicon-germanium alloy layers, and/or any other suitable layers. Various layers can be used as hosts of memory cells, transistors, separations between memory cells/transistors, and/or the like.

At block 512, method 500 includes obtaining optical inspection data characterizing a profile of the deformation of the first substrate, e.g., measuring the shape of the substrate, such as a displacement of a surface (e.g., the top surface) of a substrate as a function of some in-plane coordinates, e.g., polar coordinates z=h(r, ϕ), Cartesian coordinates, z=h (x, y), or any other suitable coordinates.

At block 514, method 500 includes decomposition of the determined shape or profile of the deformation of the substrate over a suitable set of polynomials, e.g., Zernike polynomials, and obtaining a set of polynomial expansion coefficients, {Aⱼ}=(A₁, A₂, A₃), A₄, A₅, A₆, A₇, . . . , each coefficient in the set characterizing a degree of presence of a particular elemental geometric shape in the wafer's deformation.

At blocks 516-518, method 500 can include optimizing the stress-modification process. Operations of block 516 can include determining a sign of stress of SCL (e.g., tensile or compressive) and operations of block 518 can include determining various parameters and characteristics of the SCL (and/or various protective films), including specific material, amount of stress, thickness, and/or the like. In one example embodiment, the SCL can be made (at least partially) of silicon nitride. In some embodiments, determining the characteristics of the SCL can be based on the optical inspection data and the polynomial decomposition of the profile (e.g., as obtained at block 514, as part of analysis of the optical inspection data). For example, an optimization software operating on a computing device can select a material based on the set of polynomial expansion coefficients, e.g., A₄, A₅, A₆, . . . . For example, selection of the SCL can be made based on the coefficient that determines a degree of parabolicity of the deformation, e.g., coefficient A₄. If the wafer is curved downwards (towards the back side of the wafer, as shown), A₄<0, a compressive SCL can be selected for the back side deposition (e.g., at subsequent block 520). If A₄>0, a tensile SCL can be selected for the back side deposition. Determining a type of a material for the SCL to be deposited and a thickness d of the SCL can be made based on multiple expansion coefficients (more than just the paraboloid bow coefficient A₄) from the set {Aⱼ} or the full profile h(r, ϕ). In one specific non-limiting example, the thickness d can be determined as follows. First, a target paraboloid deformation Ã₄ can be determined that is sufficient to overcompensate for the measured wafer deformation, e.g., for h(r, ϕ)<0, the following condition can be satisfied:

$${Ã}_{4} {Z}_{4} ( ρ , ϕ ) + h ( r , ϕ ) ≡ ( {Ã}_{4} + {A}_{4} ) {Z}_{4} ( ρ , ϕ ) + {A}_{5} {Z}_{5} ( ρ , ϕ ) + {A}_{5} {Z}_{6} ( ρ , ϕ ) + … > 0.$$

In other words, the target paraboloid deformation Ã₄ can be chosen sufficiently large to compensate for the paraboloid deformation (A₄), saddle deformation (A₅ and A₆) and the residual deformation (A₇ and higher coefficients). In some embodiments, the target paraboloid deformation Ã₄ can be selected with at least an excess magnitude A_{X} over the minimum needed to overcompensate for the wafer deformation, e.g.,

$${Ã}_{4} {Z}_{4} ( ρ , ϕ ) + h ( r , ϕ ) > {A}_{X} {Z}_{4} ( ρ , ϕ ) .$$

The excess magnitude A_{X} can be empirically selected and can depend on the specific material used for the SCL.

Once the target paraboloid deformation Ã₄ has been determined, the thickness d of the SCL can be selected using calibration data that tabulates or otherwise defines a function d=ƒ(Ã₄). In some embodiments, the function ƒ(A₄) can be a nonlinear function. In some embodiments, the function ƒ(Ã₄) can be a linear function, d=αÃ₄, with a coefficient of proportionality a determined based on mathematical modeling of elastic equations for specific SCL material(s), using empirical calibration, or any combination thereof. In some embodiments, thickness d of the SCL is selected to make deformation h_{corr}(r, ϕ) of a uniaxial type (e.g., cylindrical) after SCL deposition.

Operations of block 518 can also include determining settings of the stress-modulation beam using the optical inspection data. The settings for the stress-modulation beam can include a type of particles of the stress-modulation beam, an energy of the particles of the stress-modulation beam, and/or an angle of incidence of the particles of the stress-modulation beam.

In some embodiments, operations of block 518 can also include determining parameters for (unidirectional or bidirectional) protective pattern (e.g., patterned mask 212 in FIG. 2C). Operations of block 518 can further include determining a direction of the protective pattern. More specifically, a processing device performing operations of block 518 can determine orientation of the principal axes of a saddle or cylindrical deformation of the wafer. The directions of the principal axes can be used to orient the directional pattern (the direction along the ridges and/or trenches in FIG. 2C). As illustrated with the inset in FIG. 5A, parameters of the protective pattern can include (but need not be limited to) a pattern period (pitch) P, trench width W, pattern thickness T, residual thickness R, and/or the like. Determining these parameters can be accomplished using modeling, simulations, solving the elasticity equations (e.g., using a finite difference analysis), or by any other suitable techniques. A given anisotropic wafer deformation, e.g., deformation h_{corr}(r, ϕ) measured or predicted to occur after deposition of SCL of a given thickness d, can be corrected using more than a single set of the parameters. For example, increasing (decreasing) trench width W for a given period P and pattern thickness T can result in decreased/increased stiffness of the SCL (e.g., in the direction perpendicular to the axis of the pattern), since the size of the protected areas in the SCL is decreased/increased. Similarly, decreased/increased stiffness of the SCL can be achieved by decreasing/increasing pattern thickness T for given period P and trench width W. Increasing resolution by decreasing period P (for a given ratio W/P) can result in a more uniform stress mitigation whereas increasing period P can facilitate stress modulations of higher amplitude (e.g., larger difference between the maximum and minimum stress).

Operations of block 518 can further include determining (e.g., computing) local dose maps for irradiation of the SCL/directional pattern. In some embodiments, the dose maps can be computed in view on the expansion coefficients A₅, A₆ (to compensate for the saddle deformation) and A₇, A₈ . . . (to compensate for the residual deformation).

At block 520, method 500 includes covering the plurality of first features with the SCL (e.g., SCL 206 in FIG. 2A). In some embodiments, at block 522, the protective pattern (e.g., patterned mask 212 in FIG. 2C) can be formed on the SCL (e.g., as computed at block 518). Formation of the protective pattern can be performed by spin-coating a photoresist, optical photolithography, imprint lithography, developing the photoresist, and/or other suitable techniques. In some embodiments, digital lithography techniques can be used instead of (or in addition to) contact printing. Optical lithography can include (but need not be limited to) contact photolithography (e.g., with a photoresist making a direct contact with the wafer), proximity photolithography (e.g., with a photoresist separated by a small gap from the wafer), and/or projection photolithography (e.g., with an optical element, such as a lens, positioned within the gap between the photoresist and the wafer).

At block 525, method 500 can include irradiating the SCL with a stress-modulation beam, e.g., to reduce (or otherwise modify) the amount of stress in the substrate/features/SCL and flatten the structure. The stress-modulation beam can include ions, photons, electrons, and/or any combination thereof, that include a beam of ions, a beam of photons, and/or a beam of electrons. In some embodiments, irradiating the SCL by the stress-modulation beam can include directing the stress-modulation beam to a plurality of edge regions of the SCL, each of the plurality of edge regions of the SCL having a width that is at or below 30% of a diameter of the substrate.

Operations of block 525 can further include various additional operations, as prescribed by the manufacturing specification, such as covering the SCL with Anti-reflective coat (ARC) or photoresist layers, removing the remnants of the directional pattern, and/or performing any other suitable operations. In some embodiments, after the SCL is deposited, a shape of the first substrate with the deposited SCL can be re-measured and the new expansion coefficients {Aⱼ} can be determined before parameters of the directional pattern are determined.

At block 530, method 500 can continue with causing a second substrate (e.g., second wafer 210 in FIG. 2D) to adhere to the first substrate on a first side covered with the plurality of first features and the SCL (e.g., see adhesion layer 214 on second wafer 210 facing the side of the first wafer 102 with features 104 and SCL 206 formed thereon in FIG. 2D).

At block 540, method 500 can include thinning the first substrate to expose at least a subset of features of the plurality of first features (e.g., as illustrated in FIG. 2F and FIG. 2G). In some embodiments, thinning the first substrate can include grinding a second side of the first substrate (e.g., a side of first wafer 102 facing up in FIG. 2E-2G), dry etching the second side of the first substrate, wet etching the second side of the first substrate, and/or applying chemical-mechanical polishing to the second side of the first substrate.

At block 550, method 500 can include forming one or more devices. An individual device of the one or more devices can include a portion of the plurality of first features, a portion of the first substrate, and a portion of the second substrate. In some embodiments, forming the one or more devices includes any, some, or all operations of block 550, as illustrated in FIG. 5B. For example, at operation 552, method 500 can include forming a second plurality of features (e.g., second set of features 240 in FIG. 2H). At least some features of the second plurality of features can be in contact with one or more exposed features of the first plurality of features. At operation 554, method 500 can include covering the second plurality of features with a protection layer (e.g., protection layer 242 in FIG. 2I). At operation 556, method 500 can include engaging the protection layer with an effector (e.g., effector 250 in FIG. 2J) to separate, from the second substrate, a structure comprising the thinned first substrate, the first plurality of features, the SCL, the second plurality of features, and the protection layer. The effector can be an electrostatic chuck, a suction chuck, and/or any other suitable effector.

At operation 558, method 500 can include cutting the structure into the one or more devices (e.g., as illustrated in FIGS. 2O-2P) and continue, at operation 560, with removing the protection layer from the one or more devices (e.g., removing protection layer 242 as illustrated in FIG. 2Q).

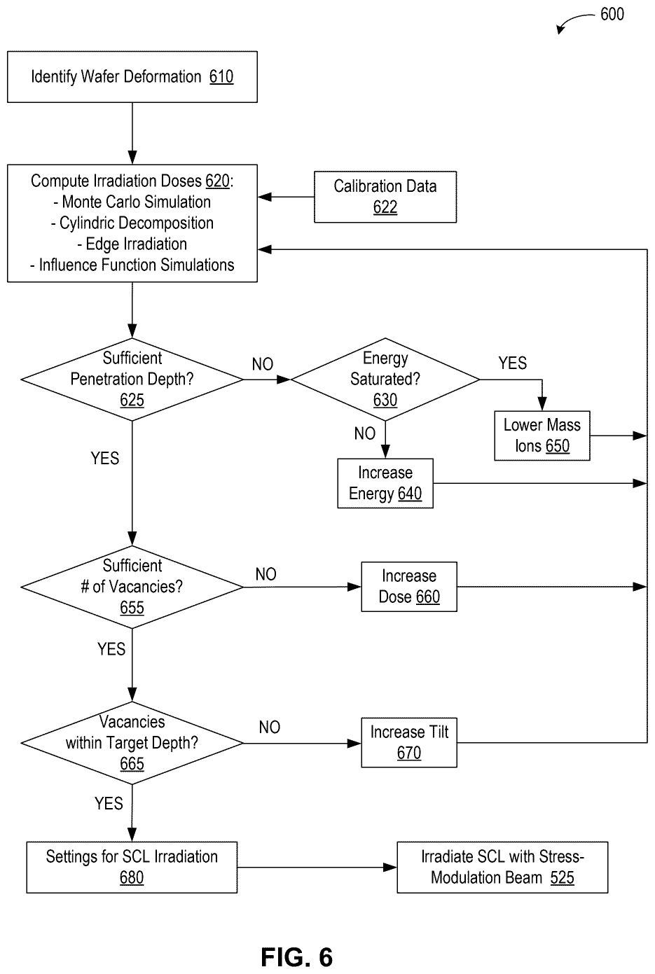

FIG. 6 is a flowchart illustrating an example method 600 of determining settings for beam irradiation, in accordance with at least one embodiment. Method 600 can be performed as part of blocks 530-590 of method 500. At block 610, method 600 can include identifying some or all of a parabolic deformation (e.g., Zernike coefficients A₄), saddle deformation (e.g., Zernike coefficients A₅, A₆), and the residual deformation (e.g., Zernike coefficients A₇, A₈ . . . ) of a wafer, e.g., using profilometry measurements.

At block 620, method 600 can continue with computing irradiation doses n (+) for the SCL deposited on the wafer. Operations of block 620 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of h_{WF}(\vec{r}), e.g., a decomposition of a saddle shape deformation into a parabolic deformation and a cylindrical deformation.

In some embodiments, irradiation doses n(\vec{r}) can be computed (and then applied at block 595) for selected edge regions of the SCL. For example, if the axis of cylindrical deformation is the y-axis, the edge regions can be regions located within some vicinity of points x=±R, y=0, where R is the radius of the wafer. Irradiation doses n(\vec{r}) near other regions (e.g., near the center of the wafer) can be significantly lower and/or zero, in some embodiments. In some embodiments, the edge regions of the SCL have a width that is at or below 30% of a diameter of the wafer. In some embodiments, the edge regions of the SCL can be exposed to a spatially uniform dose of particles of the stress-modulation beam, a radially-varying dose of particles of the stress-modulation beam, or an azimuthally-varying dose of particles of the stress-modulation beam. In some embodiments, irradiation doses n(\vec{r}) can be spread out more uniformly across the area of the wafer, e.g., can be non-zero both near the edges and near the middle of the wafer. In some embodiments, irradiation doses n(\vec{r}) can be uniform (constant) throughout the area of the wafer while the uniformity of stress-modulation is achieved by the deposited protective pattern having spatially-varying parameters (e.g., width W, period P, thickness T, etc.).

In some embodiments, irradiation doses n(\vec{r}) can be computed using an influence function G(\vec{r}; \vec{r}′), also known as the Green's function, which characterizes a response (e.g., deformation) of the wafer at a point \vec{r} of the wafer as caused by a point-like force applied at a point \vec{r}′ of the wafer. In some embodiments, the influence function G(\vec{r}; \vec{r}′) can be determined from computational simulations or analytical calculations. In some embodiments, the influence function can be determined from one or more experiments, which can include performing ion implantation into a film deposited on a reference wafer. In some embodiments, a combination of multiple techniques of determining the influence function G(\vec{r}; \vec{r}′) can be used.

As a way of example, the Monte Carlo simulations for a structure (e.g., wafer with films and an SCL deposited thereon) can be performed for specific materials of the structure (e.g., silicon wafer, stack of films, and/or the like) and for a specific thickness of the structure. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the SCL (e.g., a default velocity of scanning and a default scanning pattern), and the like.

In some embodiments, various techniques of irradiation dose computations can use calibration data 622 collected for actual irradiation performed for various types of the irradiation beams, energies of the irradiation beams, types and materials of structures being irradiated, angles of beam incidence on the structures, and/or the like. In some embodiments, calibration data 622 can be statistically preprocessed. For example, various measurements can be collected for multiple wafer/films/SCL materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 620 can include sampling from the stored distributions and identifying a likelihood that a target stress mitigation will be achieved with the default settings of conditions of beam irradiation of a SCL of a given type and thickness. Method 600 can include several verification operations designed to determine whether the target stress can be achieved without detrimentally affecting properties of the wafer/films. For example, at block 625, method 600 can include verifying if the penetration depth of the selected (e.g., default) type of particles is sufficient. For example, the penetration depth is to be at least a certain fraction of the thickness of the SCL, e.g., 20%, 30%, 50%, 80%, or more of that thickness. In some embodiments the penetration depth can be up to 100% of the thickness. If the energy is insufficient, method 600 can include checking, at block 630, if the irradiation beam source is capable of outputting particles of a higher energy. If higher energies are available, method 600 can continue with increasing the energy of the particles (block 640) and repeating irradiation dose computations of block 620 for the increased energy. If the maximum energy of the irradiation beam source has already been reached, method 600 can continue with replacing (at block 650) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 655, method 600 can include verifying whether the number of expected formed vacancies is sufficient. To verify sufficiency, method 600 can assess stress mitigation caused by formed vacancies. In one embodiment, method 600 can begin at some value of stress in the SCL, e.g., −3.0 GPa or some other suitable value (negative sign indicating compressive stress) and use beam irradiation to mitigate this stress towards a neutral point, 0.0 GPa at various locales of the SCL.

If the number of vacancies is insufficient, method 600 can include increasing a dose of particles (at block 660) and repeating irradiation dose computations of block 620 for the increased dose.

At block 665, method 600 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the wafer/films and affecting properties of the wafer/films. If the vacancies are to be formed at depths that exceed the target depth, method 600 can include (at block 670) increasing an angle of incidence (e.g., by tilting the irradiation beam) to keep vacancies (as well as substitution impurities) to a shallower region of the SCL.

Blocks 620-670 can be repeated multiple times until irradiation dose computations of block 620 are determined to be sufficient that the desired stress mitigation can be achieved, e.g., that the reduction in the tensile stress of the SCL is such that the deformation of the wafer is eliminated or at least reduced to an acceptable tolerance. The final settings for SCL irradiation (block 680) determined from irradiation dose computations can then be used for irradiation of the SCL with the stress-modulation beam (at block 525).

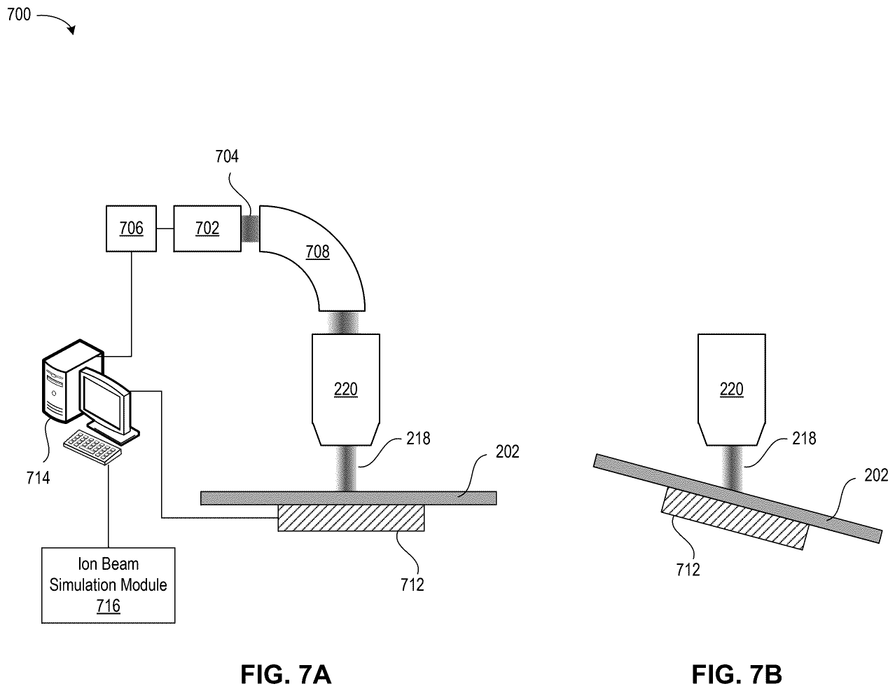

FIG. 7A illustrates schematically an irradiation system 700 capable of performing irradiation of stress compensation layers, according to at least one embodiment. Irradiation system 700 can include collimating and focusing column 220 of FIGS. 2B-2C. Irradiation system 700 can further include a beam source 702 for producing a source beam 704. Beam source 702 can include a chamber for generating ions (e.g., a plasma chamber), a light source for generating photons (e.g., a laser, laser diode, lamp, etc.), a heated filament for producing electrons, and/or any other source for the particles of a type deployed in specific stress-modulation techniques of the instant disclosure. Beam source 702 can be powered by a power element 706 and can include an extraction electrode assembly (not shown). Irradiation system 700 can include a mass spectrometer 708 (e.g., in the instances where beam source 702 produces charged particles, such as electrons or ions) and a collimating and focusing column 220. Collimating and focusing column 220 can direct stress-modulation beam 218 to wafer 202. Wafer 202 can be supported by a support stage 712. In some embodiments, support stage 712 and wafer 202 can remain stationary during irradiation of wafer 202 by stress-modulation beam 218 while components of irradiation system 700 can be repositioned relative to wafer 202. In some embodiments, irradiation system 700 can be stationary while support stage 712 can reposition wafer 202. In some embodiments, stress-modulation beam 218 can have intensity (e.g., light intensity) that is modulated by changing intensity of beam source 702 and/or placing a partially absorbing or partially reflecting material at some location between beam source 702 and wafer 202. This enables delivery of local irradiation doses n(x, y) to various locations of wafer 202. Scanning with stress-modulation beam 218 can occur along multiple directions, e.g., along x-axis and along y-axis according to any suitable predetermined pattern, e.g., back-and forth along x-axis, in a spiral pattern, and so on. In various embodiments, stress-modulation beam 218 can be scanned with a frequency of several Hz, tens of Hz, hundreds of Hz, thousands of Hz, or more.

Operations of irradiation system 700 can be controlled by a controller 714, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 714 can control operations of power element 706, support stage 712, and/or various other components and modules of irradiation system 700. Controller 714 can include a stress-modulation module 716 capable of performing simulations that determine a target intensity of stress-modulation beam 218 to be used to mitigate various wafer deformations. In some embodiments, as illustrated in FIG. 7B, support stage 712 can impart a tilt, e.g., in one or two spatial directions to wafer 202 to change an angle of incidence of stress-modulation beam 218 relative to wafer 202. In some embodiments, instead of tilting wafer 202, controller 714 can cause a tilt of stress-modulation beam 218 relative to wafer 202.

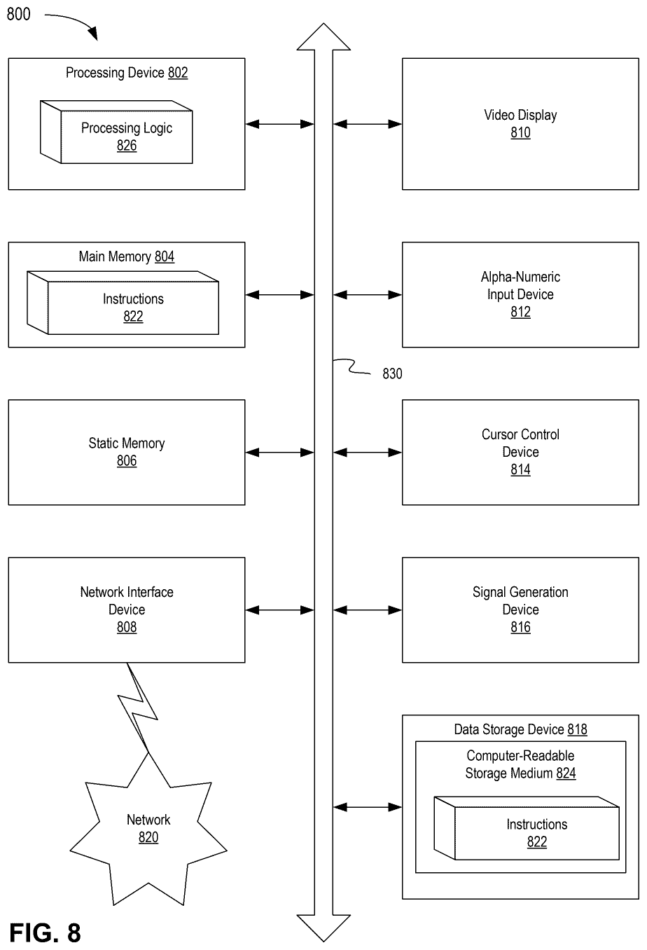

FIG. 8 depicts a block diagram of an example computer system 800 capable of supporting operations of the present disclosure, according to at least one embodiment. In various illustrative examples, example computer system 800 may be or include controller 714 of FIG. 7. Example computer system 800 may be connected to other computer systems in a LAN, an intranet, an extranet, and/or the Internet. Computer system 800 may operate in the capacity of a server in a client-server network environment. Computer system 800 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 800 may include a processing device 802 (also referred to as a processor or CPU), a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which may communicate with each other via a bus 830.

Processing device 802 represents one or more general-purpose processing devices such as a microprocessor, central processing unit, or the like. More particularly, processing device 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 802 may include a processing logic 826 configured to execute instructions (e.g., instructions 822) implementing example method 500 of mitigation of anisotropic wafer stress and deformation using stress-compensation beams with directional pattern and/or method 600 of determining settings for beam irradiation.

Example computer system 800 may further comprise a network interface device 808, which may be communicatively coupled to a network 820. Example computer system 800 may further comprise a video display 810 (e.g., a liquid crystal display (LCD), a touch screen, or a cathode ray tube (CRT)), an alphanumeric input device 812 (e.g., a keyboard), a cursor control device 814 (e.g., a mouse), and an acoustic signal generation device 816 (e.g., a speaker).

Data storage device 818 may include a computer-readable storage medium (or, more specifically, a non-transitory computer-readable storage medium) 824 on which is stored one or more sets of executable instructions 822. In accordance with one or more aspects of the present disclosure, executable instructions 822 may comprise executable instructions implementing example method 500 of mitigation of anisotropic wafer stress and deformation using stress-compensation beams with directional pattern and/or method 600 of determining settings for beam irradiation.

Executable instructions 822 may also reside, completely or at least partially, within main memory 804 and/or within processing device 802 during execution thereof by example computer system 800, main memory 804 and processing device 802 also constituting computer-readable storage media. Executable instructions 822 may further be transmitted or received over a network via network interface device 808.

While the computer-readable storage medium 824 is shown in FIG. 8 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method of manufacturing one or more devices, the method comprising:
forming a plurality of first features on a first side of a first substrate;
covering the plurality of first features with a stress-compensation layer (SCL);
causing a second substrate to adhere to the first substrate on a first side covered with the plurality of first features and the SCL;
thinning the first substrate to expose at least a subset of features of the plurality of first features; and
forming the one or more devices, each device of the one or more devices comprising a portion of the plurality of first features, a portion of the first substrate, and a portion of the second substrate, wherein the SCL is selected to reduce deformation of the one or more devices.

2. The method of claim 1, wherein the first plurality of features comprises:
one or more transistors, or
interconnect circuitry.

3. The method of claim 1, wherein the SCL comprises silicon nitride.

4. The method of claim 1, wherein thinning the first substrate comprises at least one of:
grinding a second side of the first substrate,
dry etching the second side of the first substrate,
wet etching the second side of the first substrate, or
applying chemical-mechanical polishing to the second side of the first substrate.

5. The method of claim 1, wherein forming the one or more devices comprises:
forming a second plurality of features, wherein at least some features of the second plurality of features contact one or more exposed features of the first plurality of features.

6. The method of claim 5, wherein forming the one or more devices further comprises:
covering the second plurality of features with a protection layer; and
engaging the protection layer with an effector to separate, from the second substrate, a structure comprising the thinned first substrate, the first plurality of features, the SCL, the second plurality of features, and the protection layer.

7. The method of claim 6, wherein forming the one or more devices further comprises:
cutting the structure into the one or more devices; and
removing the protection layer from the one or more devices.

8. The method of claim 1, further comprising:
irradiating, prior to causing the second substrate to adhere to the first substrate, the SCL with a stress-modulation beam comprising at least one of: a beam of ions, a beam of photons, or a beam of electrons.

9. The method of claim 8, wherein irradiating the SCL by the stress-modulation beam comprises:
forming a spatially-modulated mask on the SCL; and
irradiating the spatially-modulated mask by the stress-modulation beam.

10. The method of claim 9, wherein the spatially-modulated mask is formed using at least one of:
contact photolithography,
proximity photolithography,
projection photolithography,
imprint lithography, or
digital lithography.

11. The method of claim 8, further comprising:
obtaining optical inspection data characterizing a profile of the deformation of the first substrate; and
determining settings of the stress-modulation beam using the optical inspection data.

12. The method of claim 11, wherein the settings for the stress-modulation beam comprise one or more of:
a type of particles of the stress-modulation beam,
an energy of the particles of the stress-modulation beam, or
an angle of incidence of the particles of the stress-modulation beam.

13. The method of claim 11, wherein obtaining the optical inspection data characterizing a profile of the deformation of the substrate comprises obtaining a polynomial decomposition of the profile of the deformation of the substrate.

14. The method of claim 8, wherein irradiating the SCL by the stress-modulation beam comprises:
directing the stress-modulation beam to a plurality of edge regions of the SCL, wherein each of the plurality of edge regions of the SCL has a width that is at or below 30% of a diameter of the substrate.

15. The method of claim 8, wherein at least one of (i) a material of the SCL, (ii) thickness of the SCL, (iii) stress of the SCL, or (iv) settings of the stress-modulation beam is determined in view of an estimated deformation, caused to the one or more devices by at least one processing operation associated with forming the one or more devices.

16. A system comprising:
a memory device d; and
a processing device communicatively coupled to the memory device, wherein the processing device causes performance of operations comprising:
forming a plurality of first features on a first side of a first substrate;
covering the plurality of first features with a stress-compensation layer (SCL);
causing a second substrate to adhere to the first substrate on a first side covered with the plurality of first features and the SCL;
thinning the first substrate to expose at least a subset of features of the plurality of first features; and
forming one or more devices, each device of the one or more devices comprising a portion of the plurality of first features, a portion of the first substrate, and a portion of the second substrate, wherein the SCL is selected to reduce deformation of the one or more devices.

17. The system of claim 16, wherein forming the one or more devices comprises:
forming a second plurality of features, wherein at least some features of the second plurality of features contact one or more exposed features of the first plurality of features.

18. The system of claim 17, wherein forming the one or more devices further comprises:
covering the second plurality of features with a protection layer; and
engaging the protection layer with a effector to separate, from the second substrate, a structure comprising the thinned first substrate, the first plurality of features, the SCL, the second plurality of features, and the protection layer.

19. The system of claim 16, wherein the operations further comprise:
irradiating, prior to causing the second substrate to adhere to the first substrate, the SCL with a stress-modulation beam comprising at least one of: a beam of ions, a beam of photons, or a beam of electrons.

20. A semiconductor manufacturing system comprising one or more processing chambers, the semiconductor manufacturing system to:
form a plurality of first features on a first side of a first substrate;
cover the plurality of first features with a stress-compensation layer (SCL);
cause a second substrate to adhere to the first substrate on a first side covered with the plurality of first features and the SCL;
thin the first substrate to expose at least a subset of features of the plurality of first features; and
form one or more devices, each device of the one or more devices comprising a portion of the plurality of first features, a portion of the first substrate, and a portion of the second substrate, wherein the SCL is selected to reduce deformation of the one or more devices.
